(19) United States
(12) Patent Application Publication
(10) Pub. No.: US 2007/0146078 A1
(43) Pub. Date: Jun. 28, 2007

(54) Selective amplifier

(76) Inventor: Christoph Bromberger, Heilbronn (DE)

Correspondence Address: MCGRATH, GEISSLER, OLDS & RICHARDSON, PLLC, P.O. BOX 1364, FAIRFAX, VA, 22038-1364, US

(21) Appl. No.: 11/646,489

(22) Filed: Dec. 28, 2006

(30) Foreign Application Priority Data
Dec. 28, 2005 (DE) DE102005062764.1

(51) Int. Cl. H03F 3/191

(52) U.S. Cl. 330/302

(57) ABSTRACT

A selective amplifier is disclosed that includes a first transistor, which has a first emitter, a first base, and a first collector, a second transistor, which has a second emitter, a second base, and a second collector, and a matching network. The first transistor is connected in the emitter circuit and the input signal acts on the first base of the first transistor. The second transistor is connected in the base circuit and the output signal can be tapped at the second collector of the second transistor. The matching network is connected directly to the first collector of the first transistor, and the matching network is connected directly to the second emitter of the second transistor.

This nonprovisional application claims priority under 35 U.S.C. § 119(a) on German Patent Application No. DE 102005062764, which was filed in Germany on Dec. 28, 2005, and which is herein incorporated by reference.

### BACKGROUND OF THE INVENTION

1. Field of the Invention

The present invention relates to a selective amplifier.

2. Description of the Background Art

A cascode circuit is known, for example, from “Analoge Schaltungen” (Analog Circuits), Seifart, 4^{th} edition, Verlag Technik, 1994, pages 101 to 106. In this case, in the cascode circuit two transistors sit “one above the other” (in a cascade). They can be realized with bipolar transistors, field-effect transistors, or a combination thereof. In the cascode circuit with bipolar transistors, the input transistor is operated in the emitter circuit and the output transistors in the base circuit. The output transistor is driven by the output current of the input transistor. The advantage of the cascode circuit is the amplification of higher frequencies. The output transistor prevents feedback by the output circuit to the input of the circuit. The voltage gain of the cascode circuit has about the same value as that of the emitter circuit at the same load resistance. In contrast to the emitter circuit, however, no large Miller capacitance occurs in the input circuit, because the voltage gain of the input transistor is very small. In this way, the top cutoff frequency during voltage control reaches virtually the magnitude of the base circuit, but at a substantially higher input resistance.

Selective amplifiers are known from pages 332 to 340. These have the task of amplifying a narrow frequency band and suppressing the other frequencies as much as possible. Selective amplifiers are very important for information transmission, e.g., for amplifying the modulated carrier signals. Monolithically integrated amplifiers are used for selective amplifiers. Selective amplifiers are made feedback-free by neutralization, so that the real portion of the input conductance cannot become negative due to a too great feedback.

### SUMMARY OF THE INVENTION

It is therefore an object of the present invention to provide a selective amplifier for the high-frequency range with as great a power gain as possible.

Therefore, a selective amplifier is provided which has a first transistor with a first emitter, with a first base, and with a first collector. Furthermore, the selective amplifier has a second transistor, which comprises a second emitter, a second base, and a second collector. Moreover, the selective amplifier has a matching network. In addition to these components, the selective amplifier may have still further components, for example, for filtering, for operating point setting, or for decoupling.

The first transistor is connected in the emitter circuit, so that the first emitter is shorted to ground AC-wise relative to the useful signal. The input signal acts on the first base of the first transistor. For this purpose, the input of the selective amplifier can be connected, for example, directly to the first base or, for example, an additional capacitor is interconnected for decoupling a DC voltage.

The second transistor is connected in the base circuit, so that the second base is shorted to ground AC-wise relative to the useful signal. The output signal can be tapped at the second collector of the second transistor. For tapping, for example, the output of the selective amplifier or an antenna can be connected directly to the second collector.

The matching network can be connected directly to the first collector of the first transistor. Furthermore, the matching network is connected directly to the second emitter of the second transistor. The matching network can be designed for an operating frequency in such a way that an especially problem-pertinent matching condition is met hereby. A matching condition is particularly an absence of feedback or a power matching. For example, a feedback of the input impedance of the second transistor to the input of the first transistor is reduced as a matching condition.

An embodiment provides that the first transistor has a lower breakdown voltage than the second transistor. In fact, contrary to a cascode circuit, the first transistor and the second transistor are separated from one another by the matching network; nevertheless, the fact applies at least for the operating frequency that the voltage swing of the output signal largely declines at the second transistor in the base circuit. This second transistor operated in the base circuit should therefore be designed for this high breakdown voltage. However, the first transistor in the emitter circuit, which sees a combined load of the matching network and second transistor, can be optimized for a high cutoff frequency and a lower breakdown voltage.

In another embodiment of the invention, a third transistor is connected in the emitter circuit and a fourth transistor in the base circuit. The first transistor, the second transistor, the third transistor, and the fourth transistor are connected to a differential amplifier. Preferably, another matching network is connected to the third transistor and the fourth transistor. Both matching networks can be symmetric to one another and connected symmetrically relative to the transistors.

According to another embodiment of the invention, a fifth transistor is provided, whereby a fifth base of the fifth transistor is connected directly to the first base of the first transistor and a fifth collector of the fifth transistor to a third collector of the third transistor.

Instead of the previously described selective amplifier with bipolar transistors, by analogy a selective amplifier can also be made with field-effect transistors. Accordingly, the object of the invention is achieved by a selective amplifier with a first transistor, which has a first source, a first gate, and a first drain. Furthermore, the selective amplifier has a second transistor, which has a second source, a second gate, and a second drain. Moreover, the selective amplifier has a matching network.

The first transistor can be connected in the source circuit. The input signal acts on the first gate of the first transistor. The second transistor is connected in the gate circuit. The output signal can be tapped at the second drain of the second transistor. The matching network is connected directly to the first drain of the first transistor and to the second source of the second transistor.

The previously explained embodiments for the selective amplifier with bipolar transistors apply accordingly also to the selective amplifier with field-effect transistors.

Variations of the invention provide that the matching network has a passive two-terminal network and/or a passive four-terminal network. The matching network can thereby comprise inductive, capacitive, or ohmic elements. In another embodiment of the invention, which can also be combined with this embodiment, the matching network moreover has nonlinear elements or active elements, such as, for example, diodes or transistors. Active and passive elements of the matching network can be integrated monolithically together with transistors thereof. The first transistor together with the matching network can be made as a unilateral four-terminal network.

Furthermore, the first transistor and/or the second transistor can have a heterojunction, particularly with a silicon-germanium mixed crystal.

The previously explained selective amplifier is advantageously used for a mobile communication device or for a radar system device with an operating frequency greater than 1 GHz.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a selective amplifier with npn bipolar transistors;

FIG. 2 illustrates a selective amplifier with NMOS field-effect transistors; and

FIG. 3 illustrates a selective amplifier as a differential amplifier.

### DETAILED DESCRIPTION

During operation of a transistor for current gain in an emitter circuit, when an ohmic load resistance is used, the transistor experiences a high voltage swing at the collector. In the equivalent electric circuit, a base-collector-capacitor can be replaced by a capacitor between the base and emitter with a capacitance value increased by a voltage gain (Miller effect). A maximum voltage swing at the collector is determined by an emitter-collector breakdown voltage.

A frequency response of a transistor operated for current gain in the emitter circuit can be increased by cascading with a transistor in the base circuit. The transistor in the emitter circuit drives only the small input resistance of the transistor in the base circuit, so that the frequency-limiting influence of the Miller effect is reduced as much as possible. Moreover, a cascode arrangement permits a higher permissible voltage swing at the collector due to base-collector breakdown voltage, which is higher by approximately a factor of three compared with the emitter-collector breakdown voltage and with which the transistor in base circuit can be supplied.

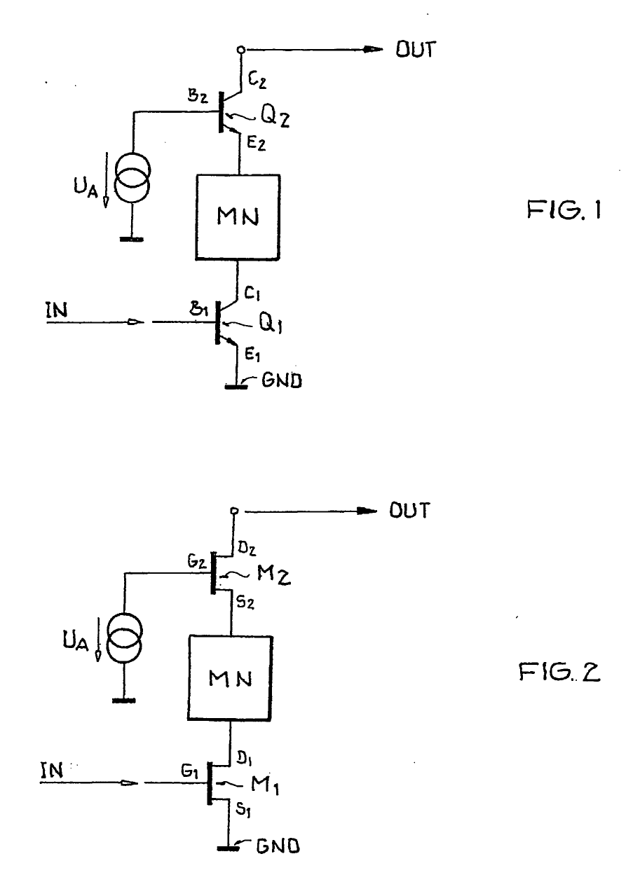

In a selective amplifier according to FIG. 1, a matching network MN is connected between a first bipolar transistor Q1 in the emitter circuit and a second bipolar transistor Q2 in the base circuit. This matching network MN is connected to a first collector C1 of first transistor Q1 and to a second emitter E2 of second transistor Q2. An input signal IN to be amplified is fed first to a first base B1 of first transistor Q1. A first emitter E1 of first transistor Q1 is connected to ground GND. A second collector C2 of second transistor Q2 is connected to an output of the selective amplifier to output an amplified output signal OUT. A second base B2 of transistor Q2 is connected to a voltage source with a voltage U_{A} to establish an operating point and shorted to ground GND for a signal frequency to be amplified.

In FIG. 1, for simplification only the components important for the AC discussion are shown schematically. Other components, necessary in particular for setting the operating point, are not shown in FIG. 1 to improve the clarity.

A maximum power gain at a given frequency of the input signal IN is achieved by a transistor with power matching at the input and output. If a transistor in the emitter circuit is optimally matched on the output side, the voltage swing, which it experiences at the collector at the given output power, is fixed. A reduction of the voltage swing at the collector of a transistor in the emitter circuit is accordingly associated with a decline in the power gain.

The matching network MN is thereby adjusted to the frequency of the input signal IN, so that the selective amplifier of FIG. 1 selectively amplifies this, whereby first transistor Q1 is optimally matchable power-wise by matching network MN for this frequency.

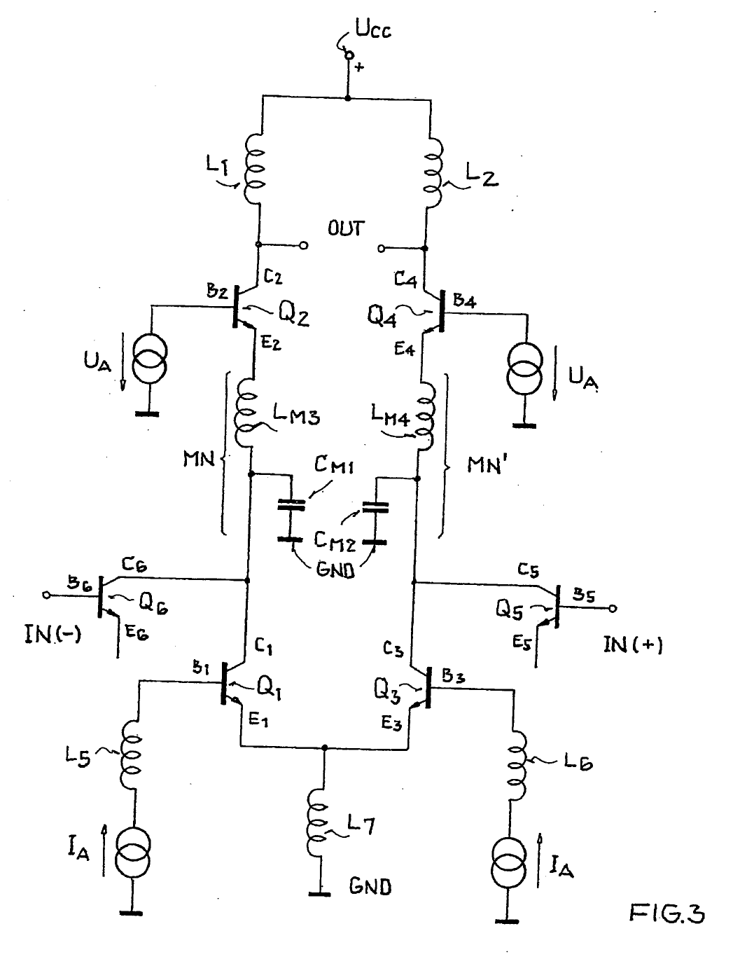

FIG. 2 shows a selective amplifier with NMOS field-effect transistors M1 and M2. A matching network MN is connected between first drain D1 of field-effect transistor M1 and second source S2 of second field-effect transistor M2. This matching network MN again enables a power-wise matching of first field-effect transistor M1 for a frequency of an input signal IN.

Analogous to FIGS. 1 and 2, selective amplifiers can also be made with pnp bipolar transistors, PMOS field-effect transistors, or a combination with bipolar and field-effect transistors.

Another exemplary embodiment with a selective amplifier as a differential amplifier is shown in FIG. 3. In this exemplary embodiment, npn bipolar transistors are used by way of example. The right and left branches of the differential amplifier are made symmetric.

Input signal IN is applied as a differential signal both to a first base B1 of a first bipolar transistor Q1 and to a third base B3 of a third bipolar transistor Q3. The left branch of the differential amplifier will be described below. Due to the symmetry, the right branch is made analogously.

A first emitter E1 of first transistor Q1 is connected to a third emitter E3 of third transistor Q3 and via a lead inductor L7 to ground GND. First transistor Q1 is furthermore connected with its collector C1 to a matching network MN. Matching network MN in this exemplary embodiment is made as a four-terminal network and has an inductor L_{M3} and a capacitor C_{M1}. The values for inductor L_{M3} and capacitor C_{M1} are adjusted to the input signal IN frequency, applied at the input, in such a way that the power gain of first transistor Q1 is optimally matched. Furthermore, the differential amplifier has another matching network MN′ with an inductor L_{M4} and a capacitor C_{M2}, whereby both matching networks MN and MN′ are made symmetric.

To reduce a base-collector capacitance of first transistor Q1 and thereby to reduce the Miller effect and to improve stability of the selective amplifier, a fifth transistor B5 is provided, which substantially has the same electrical properties, particularly a similar geometry, as first transistor Q1. A fifth base B5 of fifth transistor Q5 is thereby directly connected to first base B1 of first transistor Q1. A fifth collector C5 of the fifth transistor Q5 is directly connected to a third collector C3 of third transistor Q3. A fifth emitter E5, on the contrary, remains open.

A second transistor Q2 and a fourth transistor Q4 are operated, as already described for FIG. 1, in the base circuit. Coils L1, L2, L5, and L6, and the current and voltage sources are used for operating point setting. The symmetric output to output the output signal OUT is connected to collectors C2 and C4 of transistors Q2 and/or Q4.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A selective amplifier comprising:
a first transistor having a first emitter, a first base, and a first collector,
a second transistor having a second emitter, a second base, and a second collector; and
a matching network,
wherein the first transistor is switchable via the first emitter and an input signal acts on the first base of the first transistor,
wherein the second transistor is switchable via the second base and an output signal is tapped at the second collector of the second transistor,
wherein the matching network is connected directly to the first collector of the first transistor, and
wherein the matching network is connected directly to the second emitter of the second transistor.

2. The selective amplifier according to claim 1, further comprising a third transistor and a fourth transistor, the third transistor being operably connected to the first transistor, the fourth transistor being operably connected to the second transistor, and the first transistor, the second transistor, the third transistor, and the fourth transistor are operably connected to a differential amplifier.

3. The selective amplifier according to claim 2, in which a second matching network is connected to the third transistor and the fourth transistor.

4. The selective amplifier according to claim 2, further comprising a fifth transistor, in which a fifth base of the fifth transistor is connected to the first base of the first transistor and a fifth collector of the fifth transistor is connected to a third collector of the third transistor.

5. A selective amplifier comprising:
a first transistor having a first source, a first gate, and a first drain;
a second transistor having a second source, a second gate, and a second drain; and
a matching network,
wherein the first transistor is connected via a source circuit and the input signal acts on the first gate of the first transistor,
wherein the second transistor is connected via a gate circuit and the output signal is tapped at the second drain of the second transistor,
wherein the matching network is connected directly to the first drain of the first transistor, and
wherein the matching network is connected directly to the second source of the second transistor.

6. The selective amplifier according to claim 5, further comprising a third transistor and a fourth transistor, the third transistor being connected to the source circuit, the fourth transistor being connected to the gate circuit, and the first transistor, the second transistor, the third transistor, and the fourth transistor being connected to a differential amplifier.

7. The selective amplifier according to claim 6, wherein a second matching network is connected to the third transistor and the fourth transistor.

8. The selective amplifier according to claim 6, further comprising a fifth transistor having a fifth gate connected to the first gate of the first transistor and a fifth drain of the fifth transistor connected to a third drain of the third transistor.

9. The selective amplifier according to claim 6, wherein the matching network meets a matching condition for absence of feedback or power matching.

10. The selective amplifier according to claim 6, in which the first transistor has a lower breakdown voltage than the second transistor.

11. The selective amplifier according to claim 6, wherein the matching network has a passive two-terminal network.

12. The selective amplifier according to claim 6, wherein the matching network has a passive four-terminal network.

13. The selective amplifier according to claim 6, in which the first transistor, together with the matching network, is made as a unilateral four-terminal network.

14. The selective amplifier according to claim 6, in which the first transistor and/or the second transistor have a heterojunction with a silicon-germanium mixed crystal.

15. The selective amplifier according to claim 1, wherein the selective amplifier is provided in a mobile communication device or a radar system device.
